(19) United States
(12) Patent Application Publication
(10) Pub. No.: US 2014/0318610 A1
(43) Pub. Date: Oct. 30, 2014

(54) SOLAR CELL AND METHOD OF FABRICATING THE SAME

(71) Applicant: LG INNOTEK CO., LTD., Seoul (KR)

(72) Inventor: Gi Gon Park, Seoul (KR)

(21) Appl. No.: 14/357,717

(22) PCT Filed: Nov. 8, 2012
(86) PCT No.: PCT/KR2012/009422

§ 371 Date: May 12, 2014

(30) Foreign Application Priority Data
Nov. 11, 2011 (KR) 10-2011-0117925

(51) Int. Cl. H01L 31/065; H01L 31/0224; H01L 31/032

(52) U.S. Cl. CPC H01L 31/065; H01L 31/0322; H01L 31/022441
USPC 136/255

(57) ABSTRACT

Disclosed are a solar cell, and a method of fabricating the same. The solar cell includes: a back electrode layer on a support substrate; a light absorbing layer on the back electrode layer; and a front electrode layer on the light absorbing layer, wherein the light absorbing layer has a bandgap energy which is gradually increased toward a top surface of the light absorbing layer.

### TECHNICAL FIELD The embodiment relates a solar cell and a method of fabricating the same.

### BACKGROUND ART

A solar cell may be defined as a device for converting light energy into electric energy by using a photovoltaic effect where electrons are produced by exposing a p-n junction diode to light. Such solar cells may be classified into a silicon solar cell, a compound semiconductor solar cell including group I-III-VI or group III-V, a dye-sensitized solar cell, and an organic solar cell according to a material used as a junction diode.

A solar cell made from CIGS (CuInGaSe), which is one of group I-III-VI Chal-copyrite-based compound semiconductors, represents superior light absorption, higher photoelectric conversion efficiency with a thin thickness, and superior electro-optic stability, so the CIGS solar cell is spotlighted as a substitute for a conventional silicon solar cell.

In general, a CISG thin film solar cell according to the related art has a structure of soda lime glass/Mo/CIGS/CdS(ZnS)/ZnO/ITO/Al. In this structure, the CIGS layer is a light absorbing layer which generates electrons and holes by solar light. Various schemes, such as a scheme of forming a Cu(In,Ga)Se₂ (CIGS) based-light absorbing layer by simultaneously or separately evaporating Cu, In, Ga, and Se and a scheme of performing a selenization process after a metallic precursor film has been formed, have been extensively used in order to form the light absorbing layer. Meanwhile, the bandgap energy of the light absorbing layer is in the range of about 1 eV to about 1.8 eV. Since a difference between the bandgap energies of the light absorbing layer and the buffer layer disposed on the light absorbing layer is great and the bandgap energy of the light absorbing layer is fixed, the photoelectric conversion efficiency is deteriorated.

### DISCLOSURE OF INVENTION

### Technical Problem

The embodiment provides a solar cell having enhanced photoelectric conversion efficiency and a method of fabricating the same.

### Solution to Problem

According to the first embodiment, there is provided a solar cell including: a back electrode layer on a support substrate; a light absorbing layer on the back electrode layer; and a front electrode layer on the light absorbing layer, wherein the light absorbing layer has a bandgap energy which is gradually increased toward a top surface of the light absorbing layer.

According to the first embodiment, there is provided a solar cell including: forming a back electrode layer on a support substrate; gradually forming a light absorbing layer on the back electrode layer; and forming a front electrode layer on the light absorbing layer, wherein the light absorbing layer has a bandgap energy which is gradually increased toward a top surface of the light absorbing layer.

According to the embodiment, there is provided a method of fabricating a solar cell, the method including the steps of: forming a back electrode layer on a support substrate; gradually forming a light absorbing layer on the back electrode layer; and forming a front electrode layer on the light absorbing layer, wherein the light absorbing layer has a bandgap energy which is gradually increased toward a top surface of the light absorbing layer.

### ADVANTAGEOUS EFFECTS OF INVENTION

The embodiment provides the solar cell including the light absorbing layer having the bandgap energy gradually increased toward the top surface of the light absorbing layer. Thus, according to the solar cell of the embodiment, electrons and holes generated by solar light can be easily transferred to the back electrode layer and the front electrode, so that power generation efficiency can be improved. In addition, the method for fabricating the solar cell according to the embodiment uses aluminum (Al) having a price lower than that of gallium (Ga) used in the related art in order to control a bandgap energy, so that the process cost can be reduced.

### BRIEF DESCRIPTION OF DRAWINGS

FIG. 1 is a sectional view showing a solar cell according to the first embodiment;

FIG. 2 is a graph showing bandgap energies of each layer of the solar cell according to the first embodiment;

FIG. 3 is a sectional view of a solar cell according to the second embodiment;

FIG. 4 is a graph showing bandgap energies of each layer of the solar cell according to the second embodiment; and

FIGS. 5 to 8 are sectional views illustrating a method of fabricating the solar cell according to the embodiment.

### MODE FOR THE INVENTION

In the description of the embodiments, it will be understood that when a substrate, a layer, a film or an electrode is referred to as being “on” or “under” another substrate, another layer, another film or another electrode, it can be “directly” or “indirectly” on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

In the description, the term of “HOMO (The Highest Occupied Molecular Orbital) level” means the highest energy level in a valence band. In addition, the term of “LUMO (The Lowest Occupied Molecular Orbital) level” means the lowest energy level in a conduction band. The term of “bandgap” used in the description means a difference between the HOMO level energy and the LUMO level energy.

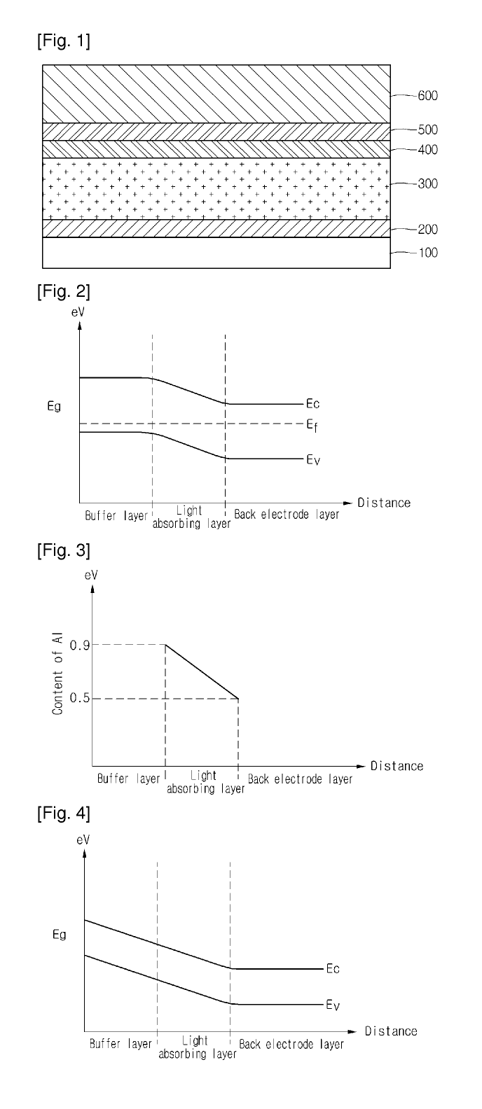

FIG. 1 is a sectional view showing a solar cell according to the first embodiment.

Referring to FIG. 1, the solar cell according to the first embodiment includes a support substrate 100, a back electrode layer 200, a light absorbing layer 300, a buffer layer 400, a high resistance buffer layer 500, and a front electrode layer 600.

The support substrate 100 has a plate shape and supports the back electrode layer 200, the light absorbing layer 300, the buffer layer 400, the high resistance buffer layer 500, and the front electrode layer 600.

The support substrate 100 may be an insulator. The support substrate 100 may include a glass substrate, a plastic substrate, or a metal substrate. In more detail, the support substrate 100 may include a soda lime glass substrate.

The support substrate 100 may be rigid or flexible. In more detail, the support substrate 100 may be a flexible substrate. For example, a material such as polymer having a flexible property may be used for the support substrate 100. Since the front electrode layer 600 of the solar cell according to the embodiment has superior mechanical property and superior flexibility, the solar cell according to the embodiment may be easily used in the field requiring flexibility if the support substrate 100 is flexible.

The back electrode layer 200 is disposed on the support substrate 100. The back electrode layer 200 is a conductive layer. The back electrode layer 200 may be formed of one among molybdenum (Mo), gold (Au), aluminum (Al), chrome (Cr), tungsten (W), and copper (Cu). Among the above materials, the Mo represents a thermal expansion coefficient similar to that of the support substrate 100, so the Mo may improve the adhesive property and prevent the back electrode layer 200 from being delaminated from the support substrate 100.

The light absorbing layer 300 is disposed on the back electrode layer 200. Further, the light absorbing layer 300 may have bandgap energy in the range of about 1.68 eV to about 2.72 eV, but the embodiment is not limited thereto.

The bandgap energy of the light absorbing layer 300 is gradually increased toward the top surface thereof. In more detail, the bandgap energy of the light absorbing layer 300 may be gradually increased from an interfacial surface between the back electrode layer 200 and the light absorbing layer 300 toward an interfacial surface between the light absorbing layer 300 and the front electrode 600. For example, the bandgap energy of the light absorbing layer 300 may be about 1.68 eV at the interfacial surface between the back electrode layer 200 and the light absorbing layer 300, and may be gradually increased, so that the light absorbing layer 300 may have the bandgap energy of about 2.72 eV at the interfacial surface between the light absorbing layer 300 and the front electrode 600.

Further, referring to FIG. 2, the bandgap energy of the light absorbing layer 300 is less than that of the buffer layer on the light absorbing layer 300 and greater than that of the back electrode layer 200.

That is, the bandgap energy of the light absorbing layer 300 may be between those of the buffer layer 400 and the back electrode layer 200 and may be gradually increased from the back electrode layer 200 toward the buffer layer 400. Thus, the solar cell according to the embodiment may be formed with the light absorbing layer having a sequential potential barrier, so that the mobility of photo-generated electrons generated from the P-N junction may be improved. Therefore, the photoelectric conversion efficiency may be improved.

The solar cell according to the first embodiment includes the light absorbing layer 300 having an impurity to allow the light absorbing layer 300 to have sequential bandgap energy. The impurity may include one selected from the group consisting of aluminum (Al), boron (B) and tantalum (Ta). In more detail, the impurity may be aluminum, but the embodiment is not limited thereto. The aluminum (Al) has bandgap energy greater than that of gallium (Ga) used for controlling the bandgap energy of the light absorbing layer in the related art. Thus, the bandgap energy of the light absorbing layer including aluminum (Al) is greater than that of the light absorbing layer including gallium (Ga), so that the photoelectric conversion efficiency of the solar cell may be improved. Further, since the aluminum (Al) has a relatively lower price compared with the gallium (Ga), the cost of a process according to the embodiment may be reduced.

As one example, the light absorbing layer 300 may include aluminum (Al) as an impurity. The light absorbing layer 300 may be expressed as the following chemical formula 1:

CuIn(Ga₁₋ₓAlₓ)Se₂(0.5≦X≦0.9) [Chemical Formula 1]

Referring to FIG. 3, the content of the aluminum may be gradually increased toward the top surface of the light absorbing layer 300. For example, the aluminum content may be about 0.5 at the interfacial surface between the back electrode layer 200 and the light absorbing layer 300 and gradually increased to be about 0.9 at the interfacial surface between the light absorbing layer 300 and the front electrode layer 600. Thus, the bandgap energy of the light absorbing layer 300 may be gradually increased toward the top surface of the light absorbing layer 300.

The buffer layer 400 is disposed on the light absorbing layer 300. The buffer layer 400 includes CdS, ZnS, InₓS_{y} and InₓSe_{y}Zn(O, OH). The high-resistance buffer layer 500 is disposed on the buffer layer 400. The high-resistance buffer layer 500 includes zinc oxide (i-ZnO) which is not doped with any impurities.

The high-resistance buffer layer 500 is disposed on the buffer layer 400. The high-resistance buffer layer 500 includes zinc oxide (i-ZnO) which is not doped with any impurities. Further, the high-resistance buffer layer may be omitted.

The front electrode layer 600 may be disposed on the light absorbing layer 300. For example, the front electrode layer 600 may be disposed to make direct contact with the high-resistance buffer layer 500.

The front electrode layer 600 may be formed of a transparent conductive material. In addition, the front electrode layer 600 may have the characteristics of an N-type semi-conductor. In this case, the front electrode layer 600 forms an N-type semiconductor together with the buffer layer 400 to make a P-N junction together with the light absorbing layer 300 serving as a P-type semiconductor layer. For instance, the front electrode layer 600 may include aluminum-doped zinc oxide (AZO). The front electrode layer 600 may have a thickness in the range of about 100 nm to about 500 nm.

FIG. 4 is a graph showing bandgap energies of each layer of the solar cell according to the second embodiment.

Referring to FIG. 4, the solar cell according to the embodiment includes the back electrode layer 200 disposed on the support substrate 100; the light absorbing layer 300 disposed on the back electrode layer 200 and including aluminum; the buffer layer 400 disposed on the light absorbing layer 300; the high-resistance buffer layer 500 disposed on the buffer layer 400; and the front electrode layer 600 disposed on the high-resistance buffer layer 500.

Further, the bandgap energies of the light absorbing layer 300 and the buffer layer 400 may be gradually increased toward the top surfaces of them, respectively. That is, the solar cell according to the second embodiment includes a structure having a sequential potential barrier from the buffer layer 400 to the light absorbing layer 300. Thus, the mobility of photo-generated electrons generated from the P-N junction may be improved. Therefore, the photoelectric conversion efficiency may be improved.

As described above, the bandgap energy of the light absorbing layer 300 is in the range of about 1.68 eV to about 2.72 eV. The bandgap energy of the light absorbing layer 300 is gradually increased in the range from the interfacial surface between the light absorbing layer and the back electrode layer toward the interfacial surface between the light absorbing layer and the buffer layer.

The bandgap energy of the buffer layer 400 is in the range of about 2.72 eV to about 3.3 eV. The bandgap energy of the buffer layer 400 is gradually increased in the range from the interfacial surface between the light absorbing layer and the buffer layer toward the interfacial surface between the buffer layer and the front electrode layer. In this case, the buffer layer 400 may be expressed as the following chemical formula 2:

ZnO_{1-y}S_{y}(0.2≦y≦0.8) [Chemical Formula 2]

In the solar cell according to the embodiment, the buffer layer 400 may have a sequential bandgap energy by controlling the contents of oxygen and sulfur. As one example, the sulfur content in the buffer layer 400 may be gradually increased from the interfacial surface between the buffer layer 400 and the high-resistance buffer layer 500 toward the interfacial surface between the buffer layer 400 and the light absorbing layer 300. For example, in the chemical formula 2, as the sulfur content (the value of y) is gradually increased from about 0.2 to about 0.5 (a), the oxygen content may be gradually decreased from about 0.8 to about 0.5. Thus, the bandgap energy of the buffer layer 400 may be gradually decreased from the interfacial surface between the buffer layer 400 and the front electrode layer 600 toward the interfacial surface between the buffer layer 400 and the light absorbing layer 300.

As another embodiment, the sulfur content in the buffer layer 400 may be gradually decreased from the interfacial surface between the buffer layer 400 and the front electrode layer 600 toward the interfacial surface between the buffer layer 400 and the light absorbing layer 300. For example, in the chemical formula 2, as the sulfur content (the value of y) is gradually decreased from about 0.8 to about 0.5 (b), the oxygen content may be gradually increased from about 0.2 to about 0.5. Thus, the bandgap energy of the buffer layer 400 may be gradually decreased from the interfacial surface between the buffer layer 400 and the front electrode layer 600 toward the interfacial surface between the buffer layer 400 and the light absorbing layer 300.

Thus, the solar cell according to the second embodiment includes a structure having a sequential potential barrier from the buffer layer 400 to the light absorbing layer 300. In addition, the mobility of photo-generated electrons generated from the P-N junction may be improved. Therefore, the photoelectric conversion efficiency may be improved.

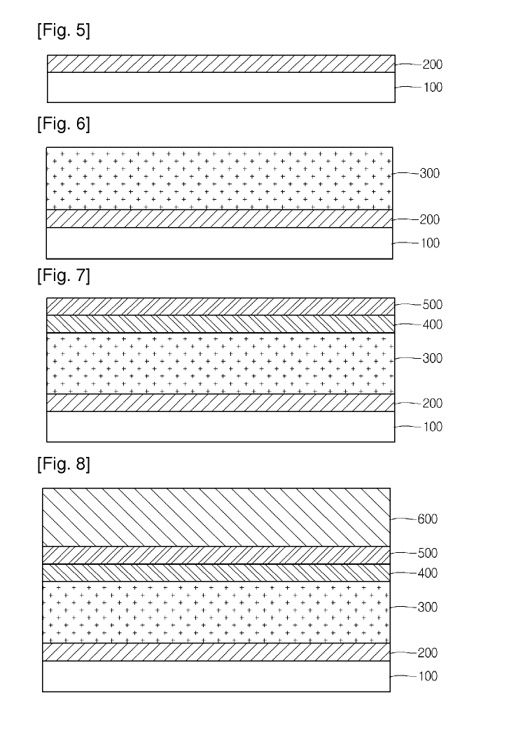

FIGS. 5 to 8 are sectional views illustrating the method for fabricating the solar cell according to the embodiment. The description related to the fabrication method refers to the description about the solar cell mentioned above.

Referring to FIG. 5, the back electrode layer 200 is formed on the support substrate 100. The back electrode layer 200 may be formed through physical vapor deposition (PVD) or plating scheme.

Next, referring to FIG. 6, the light absorbing layer 300 is formed on the back electrode layer 200. As one embodiment for fabricating the light absorbing layer 300, the Cu(In,Ga)Se₂ (CIGS) based-light absorbing layer 300 may be formed by simultaneously or separately evaporating Cu, In, Ga, and Se. In this case, while the process for fabricating the light absorbing layer 300 proceeds, the aluminum content in the light absorbing layer 300 may be controlled by increasing an aluminum-evaporating rate. In addition, only a few amount of gallium (Ga) may be evaporated or the gallium (Ga) may be except from the evaporation, but the embodiment is not limited thereto.

As another embodiment for fabricating the light absorbing layer 300, the light absorbing layer 300 may be formed through a scheme of performing a selenization process after a metallic precursor film including Cu, In, Ga, Al and Se has been formed, which has been extensively used. In detail, the metal precursor layer is formed on the back electrode layer 200 by performing the sputtering process using a Cu target, an In target, a Ga target and an Al target. The aluminum content in the light absorbing layer 300 may be controlled by controlling the sputtering power. For instance, while the process proceeds, the aluminum content in the light absorbing layer 300 may be increased by increasing the sputtering power.

Then, the CIGS based-light absorbing layer 300 doped with CuIn(Ga₁₋ₓ, Alₓ)Se₂; Al is formed by performing the selenization process after a metallic precursor film has been formed.

The sputtering process using a Cu target, an In target, a Ga target and an Al target and the selenization process may be simultaneously performed.

Alternatively, the CIS or CIG based-light absorbing layer 300 including aluminum may be formed by performing the sputtering process using either Cu target and an In target or a Cu target, an In target, a Ga target and an Al target, and the selenization process.

Referring to FIG. 7, the buffer layer 400 and the high-resistance buffer layer 500 are formed by steps on the light absorbing layer 300. If a method for fabricating the buffer layer 400 is known in the art, the method may be used without any other particular limitations. For example, the buffer layer 400 may be fabricated through Chemical Bath Deposition (CBD), Atomic Layer Deposition (ALD) or Metal-organic Chemical Vapor Deposition (MOCVD).

As one embodiment, the buffer layer 400 may be fabricated through Chemical Bath

Deposition (CBD) as will be described below. Zinc sulfuric acid (ZnSO) and thiourea (NHCS) solutions are used as zinc and sulfuric. Ammonia (NH) is used as complex and pH adjuster. A suitable amount of hydrozinehydrate solution may be added to a reactive solution to accelerate the generation of zinc ions. That is, in order to grow a zinc sulfuric (ZnS) thin film, ZnSO, NH₃, hydrozinehydrate and thiourea aqueous solution reagents are added into a reaction container containing a suitable amount of deionized water in sequence of ZnSO, NH₃, hydrozinehydrate and thiourea. At this time, the temperature of the support substrate 100 may be controlled to be in the range of about 50° C. to about 90° C. by using a heater installed in the reaction vessel.

Further, by controlling the reaction temperature with two steps or more, the buffer layer 400 having the sequential bandgap energy may be fabricated. For instance, oxygen is mainly reacted under the temperature condition in the range of about 50° C. to about 60° C. and sulfur is mainly reacted under the temperature condition in the range of about 70° C. to about 90° C., such that the buffer layer 400 having the sequential bandgap energy may be fabricated. As another embodiment, when the buffer layer 400 is fabricated through ALD (Atomic Layer Deposition) and MOCVD, the bandgap energy of the buffer layer 400 may be gradually controlled by controlling a partial pressure of gas. The high-resistance buffer layer 500 may be gradually formed on the buffer layer 400.

Referring to FIG. 8, the high-resistance buffer layer 500 may be formed by depositing zinc oxide on the buffer layer 400 through a sputtering process. The front electrode layer 600 may be formed through a deposition scheme using a ZnO target according to an RF sputtering scheme, a reaction sputtering scheme using a Zn target, or a metal organic chemical vapor deposition.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a back electrode layer on a support substrate;
a light absorbing layer on the back electrode layer; and
a front electrode layer on the light absorbing layer,
wherein the light absorbing layer has a bandgap energy which is gradually increased toward a top surface of the light absorbing layer.

2. The solar cell of claim 1, wherein the bandgap energy of the light absorbing layer is gradually increased from an interfacial surface between the light absorbing layer and the back electrode layer toward an interfacial surface between the light absorbing layer and the front electrode layer.

3. The solar cell of claim 1, wherein the bandgap energy of the light absorbing layer is in a range of 1.68 eV to 2.72 eV.

4. The solar cell of claim 1, wherein the light absorbing layer includes one of aluminum (Al), boron (B) and tantalum (Ta).

5. The solar cell of claim 4, wherein the light absorbing layer is expressed as CuIn(Ga₁₋ₓAlₓ)Se₂(0.5≦X≦0.9).

6. The solar cell of claim 5, wherein a content of the aluminum in the light absorbing layer is gradually increased toward a top surface of the light absorbing layer.

7. The solar cell of claim 1, further comprising a buffer layer between the light absorbing layer and the front electrode layer,
wherein the buffer layer has a bandgap energy which is gradually increased toward a top surface of the buffer layer.

8. The solar cell of claim 7, wherein the bandgap energy of the buffer layer is gradually increased from an interfacial surface between the light absorbing layer and the buffer layer toward an interfacial surface between the buffer layer and the front electrode layer.

9. The solar cell of claim 7, wherein the bandgap energy of the buffer layer is in a range of 2.72 eV to 3.3 eV.

10. The solar cell of claim 7, wherein the buffer layer includes oxygen (0) and sulfur (S), x.

11. The solar cell of claim 10, wherein a content of the sulfur in the buffer layer is gradually increased or decreased toward a top surface of the buffer layer.

12-15. (canceled)

16. The solar cell of claim 7, wherein the buffer layer is expressed as ZnO_{1-y}S_{y}(0.2≦y≦0.8).

17. The solar cell of claim 7, wherein the bandgap energy of the light absorbing layer is less than the bandgap energy of the buffer layer.

18. The solar cell of claim 7, wherein the bandgap energy of the light absorbing layer is greater than the bandgap energy of the back electrode layer.

19. The solar cell of claim 7, wherein the bandgap energy of the light absorbing layer is between the bandgap energy of the buffer layer and the bandgap energy of the back electrode layer.

20. The solar cell of claim 7, wherein the bandgap energy of the light absorbing layer is gradually increased from the back electrode layer toward the buffer layer.

21. The solar cell of claim 10, further comprising a high-resistance buffer layer on the buffer layer.

22. The solar cell of claim 21, wherein the high-resistance buffer layer includes zinc oxide (i-ZnO) and the high-resistance buffer layer is not doped with any impurities.

23. The solar cell of claim 21, wherein the sulfur content in the buffer layer is gradually increased from a interfacial surface between the buffer layer and the high-resistance buffer layer toward a interfacial surface between the buffer layer and the light absorbing layer.

24. The solar cell of claim 10, wherein the sulfur content in the buffer layer is gradually decreased from an interfacial surface between the buffer layer and the front electrode layer toward the interfacial surface between the buffer layer and the light absorbing layer.
